(19) United States
(12) Patent Application Publication
(10) Pub. No.: US 2025/0155794 A1
(43) Pub. Date: May 15, 2025

(54) OPTICAL PROXIMITY CORRECTION METHOD AND METHOD OF MANUFACTURING MASK BY USING THE SAME

(71) Applicant: Samsung Electronics Co., Ltd., Suwon-si (KR)

(72) Inventors: Kyeonghwan KANG, Suwon-si (KR); Hungbae AHN, Suwon-si (KR); Sangoh PARK, Suwon-si (KR)

(73) Assignee: Samsung Electronics Co., Ltd., Suwon-si (KR)

(21) Appl. No.: 18/656,776

(22) Filed: May 7, 2024

(30) Foreign Application Priority Data
Nov. 15, 2023 (KR) 10-2023-0158621

(51) Int. Cl. G03F 1/36; G03F 1/76

(52) U.S. Cl. CPC G03F 1/36; G03F 1/76

(57) ABSTRACT

Some example embodiments provide an optical proximity correction (OPC) method using an OPC model having improved performance and/or a method of manufacturing a mask by using the OPC method. An OPC method includes receiving a design layout of a target pattern, generating a first OPC model on the design layout, in which an optical effect of an exposure process is reflected, generating a second OPC model in which a characteristic of a photoresist in the exposure process is reflected, and performing a simulation using the first and second OPC models to obtain an OPC-performed design layout. The generating the second OPC model includes differently applying a combination of kernel functions, used in the second OPC model, to each pattern region.

### CROSS-REFERENCE TO RELATED APPLICATION

This application is based on and claims priority under 35 U.S.C. § 119 to Korean Patent Application No. 10-2023-0158621, filed on Nov. 15, 2023, in the Korean Intellectual Property Office, the disclosure of which is incorporated by reference herein in its entirety.

### BACKGROUND

Various example embodiments relate to a method of manufacturing a mask, and more particularly, to an optical proximity correction (OPC) method and/or a method of manufacturing a mask by using the OPC method.

In a semiconductor process, photolithography using a mask may be performed for forming a pattern on a semiconductor substrate such as a wafer. To simply provide a definition, a mask may be referred to as a pattern transfer artifact or apparatus where a pattern including an opaque material is formed on a transparent base material. To briefly describe a manufacturing process of a mask, a circuit such as a desired circuit is first designed, a layout of the circuit is designed, and design data obtained through optical proximity correction (OPC) is transferred as mask tape-out (MTO) design data. Subsequently, mask data preparation (MDP) may be performed based on the MTO design data, and an exposure process may be performed on a substrate for mask.

### SUMMARY

Various example embodiments may provide an optical proximity correction (OPC) method using an OPC model having improved performance and/or to a method of manufacturing a mask by using the OPC method.

Inventive concepts are not limited to the aforesaid, but other objects not described herein will be clearly understood by those of ordinary skill in the art from descriptions below.

An optical proximity correction (OPC) method according to various example embodiments includes receiving a design layout of a target pattern, generating on the design layout a first OPC model of, in which an optical effect of an exposure process is reflected, generating a second OPC model in which a characteristic of a photoresist in the exposure process is reflected, and performing a simulation using the first and second OPC models to obtain an OPC-performed design layout. The generating the second OPC model includes differently applying a combination of kernel functions, used in the second OPC model, to each pattern region.

Alternatively or additionally an optical proximity correction (OPC) method according to various example embodiments includes receiving a design layout of a target pattern, generating a first OPC model on the design layout, in which an optical effect of an exposure process is reflected, generating a second OPC model in which a characteristic of a photoresist in the exposure process is reflected, and performing a simulation using the first and second OPC models to obtain an OPC-performed design layout. The generating the second OPC model includes determining a significance for each pattern region of the target pattern, based on the significance applying a combination of different kernel functions to generate region-based resist models, and combining the region-based resist models to provide the second OPC model.

Alternatively or additionally a method of manufacturing a mask according to various example embodiments includes receiving a design layout of a target pattern, generating a first OPC model on the design layout, in which an optical effect of an exposure process is reflected, generating a second OPC model in which a characteristic of a photoresist in the exposure process is reflected, performing a simulation using the first and second OPC models to obtain an OPC-performed design layout; transferring data of an OPC-performed design layout as mask tape-out (MTO) design data, preparing mask data based on the MTO design data, and performing exposure on a substrate for mask, based on the mask data. The generating the second OPC model includes differently applying a combination of kernel functions, used in the second OPC model, to each pattern region.

### BRIEF DESCRIPTION OF THE DRAWINGS

Various example embodiments will be more clearly understood from the following detailed description taken in conjunction with the accompanying drawings in which:

FIG. 1 is a flowchart schematically illustrating a process of an optical proximity correction (OPC) method according to some example embodiments;

FIGS. 2A to 2C are concept diagrams for respectively describing operations of the OPC method of FIG. 1;

FIG. 3 is a flowchart illustrating in more detail an operation of generating a second OPC model in the OPC method of FIG. 1;

FIGS. 4A to 4D are concept diagrams for respectively describing operations of generating the second OPC model of FIG. 3;

FIGS. 5A and 5B are perspective views for comparing and describing a wet development process of a comparative example and a dry development process associated with an OPC method according to some example embodiments;

FIGS. 6A and 6B are graphs showing a comparison result of performance of an OPC model of an OPC method of a comparative example and performance of an OPC model of an OPC method according to some example embodiments; and

FIG. 7 is a flowchart schematically illustrating a process of a method of manufacturing a mask by using an OPC method, according to some example embodiments.

### DETAILED DESCRIPTION OF VARIOUS EXAMPLE EMBODIMENTS

Hereinafter, some example embodiments will be described in detail with reference to the accompanying drawings. Like reference numerals refer to like elements in the drawings, and their repeated descriptions are omitted.

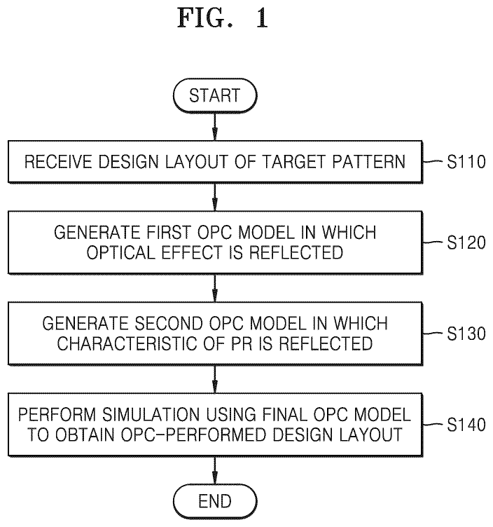

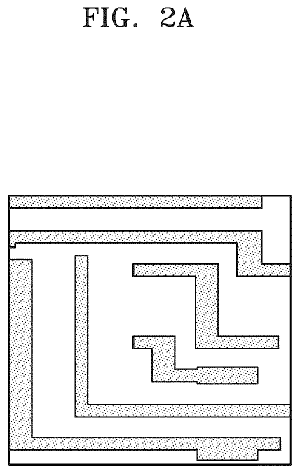

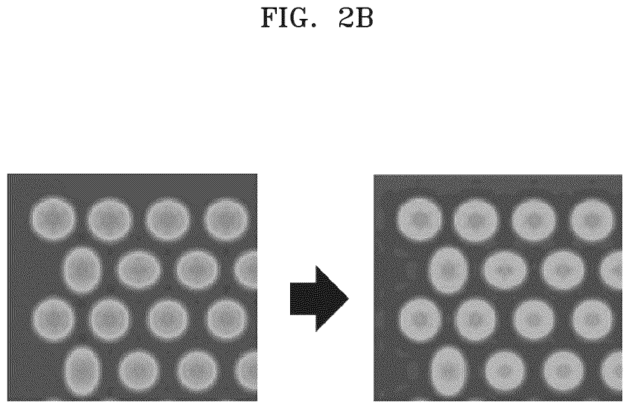

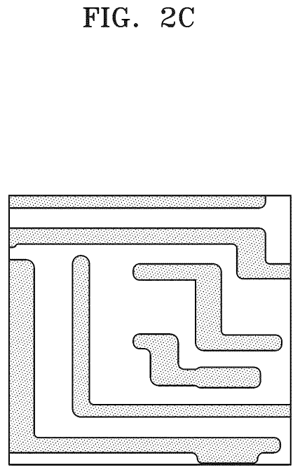

FIG. 1 is a flowchart schematically illustrating a process of an optical proximity correction (OPC) method according to some example embodiments, and FIGS. 2A to 2C are concept diagrams respectively illustrating operations of the OPC method of FIG. 1.

Referring to FIGS. 1 to 2C, in operation S110, the OPC method according to some example embodiments may first receive a design layout of a target pattern which is to be formed on a substrate. Here, the target pattern may denote or correspond a pattern which is to be formed on a substrate such as a silicon (Si) wafer. For example, a pattern of a mask may be transferred onto a substrate through an exposure process, and thus, a target pattern may be formed on or in the substrate. In some example embodiments, the pattern of the mask may be reduced and projected and may then be transferred onto the wafer, and thus, the pattern of the mask may have a size which is greater than that of the target pattern on the substrate.

The design layout may denote or correspond to a layout of the pattern of the mask corresponding to the target pattern. The shape of the target pattern of the wafer may differ from that of a pattern of a real mask used in an exposure process, in terms of a characteristic of the exposure process. However, the shape of a first design layout of the pattern of the mask may be substantially the same as that of the target pattern of the wafer. FIG. 2A illustrates a design layout of a pattern of a mask corresponding to a target pattern. Generally, a design layout may have a shape of a right-angled design layout. The shape of the right-angled design layout may denote a shape where edges are configured with only straight and sharp lines and sharp, e.g., ninety-degree, angles. For example, as illustrated in FIG. 2A, the design layout may have a shape where a rectangular shape, which is long and extends in a first (horizontal) direction, is coupled to a rectangular shape, which is long and extends in a second (vertical) direction. However, the shape of the design layout is not limited to a shape of the right-angled design layout.

Subsequently, a first OPC model in which an optical effect of an exposure process is reflected may be generated on the design layout in operation S120. Generally, the first OPC model may be referred to as an optical OPC model. The optical OPC model may correspond to a portion of an OPC model which is used as a simulation, in the OPC method.

For reference, as a pattern of a mask is fined, an optical proximity effect (OPE) caused by an effect between adjacent patterns may occur in an exposure process, and the OPC method may denote or correspond to a method which corrects or improves a design layout of the pattern of the mask, to prevent or reduce the impact of and/or the probability of occurrence of the OPE. For example, due to the OPE, the size and/or shape of a pattern formed on a wafer may be changed by the pattern density and/or the arrangement of a mask, and to correct or improve upon the change, the OPC method may be performed. Various methods, such as rule-based and/or model-based methods, may be used in performing OPC, but correction using the OPC model may be mainly performed.

The OPC method may be largely categorized into two methods, and one of the two methods may be a rule-based OPC method and the other may be a simulation-based or a model-based OPC method. The OPC methods may use either or both rule-based and model-based methods. The model-based OPC method may use only a measurement result of representative patterns without needing or using all of massive test patterns and may thus have advantages in terms of time and/or cost. The OPC method according to some example embodiments may be, for example, a model-based OPC method, namely, a correction method using an OPC model. Here, the OPC model may be a simulation model which outputs the shape of an exposure result to a wafer, on a design layout of a certain pattern of a mask, and may reflect a mask, an optical effect, and a resist characteristic to output a simulation image.

Alternatively or additionally, the OPC method may include a method which adds sub-lithographic features, called serifs, to a corner of a pattern, or sub-resolution assist features (SRAFs) such as scattering bars and/or in riggers and/or outriggers, in addition to a modification of a layout of the pattern. Here, the SRAFs may be or may include tetragonal features disposed on each corner of a pattern generally and may be used for compensating for a distortion factor caused by intersection of the pattern and/or sharpening of corners of the pattern. The SRAF may be or correspond to a secondary feature which is introduced for solving or improving upon an OPC deviation problem caused by a density difference of the pattern, and as a sub-resolution assist feature may be a feature which is formed with a size which is less than a resolution of exposure equipment and is not transferred onto a resist layer.

The OPC method may prepare basic data for OPC. Here, the basic data may include one or more of data of shapes of patterns of a sample, positions of the patterns, the kind of measurement such as measurement of a space or line of each pattern, and a basic measurement value. Alternatively or additionally, the basic data may include information about one or more of the thickness, refractive index, and dielectric constant of a photoresist, and/or may include a source map of an illumination system form. However, the basic data is not limited to pieces of data described above.

After the basic data is prepared, the first OPC model (e.g., an optical OPC model) may be generated. An operation of generating an OPC model may include an operation of optimizing or improving a defocus stand (DS) position and a best focus (BF) position in the exposure process. In some example embodiments, an operation of generating the optical OPC model may include an operation of generating a mask image based on a diffraction phenomenon of light and/or on an optical state of exposure equipment. However, the operation of generating the optical OPC model is not limited to the above descriptions. For example, the operation of generating the optical OPC model may include various details associated with an optical effect in the exposure process. For example, an operation of calculating an optical mask image (e.g., a near-field image of a mask) based on an effect of a mask topography may be first performed in association with generating of the OPC model. The operation of calculating the near-field image of the mask may use a rigorous simulation method such as a rigorous coupled-wave analysis (RCWA) and/or finite difference time domain (FDTD) simulation, and/or may use an edge filter for calculating the near-field image of the mask.

After or at least partly after the first OPC model is generated, a second OPC model in which a characteristic of a photoresist (PR) is reflected may be generated in operation S120. Generally, the second OPC model may be referred to as an OPC model for PR. The OPC model for PR may correspond to a portion of an OPC model which is used in the OPC method.

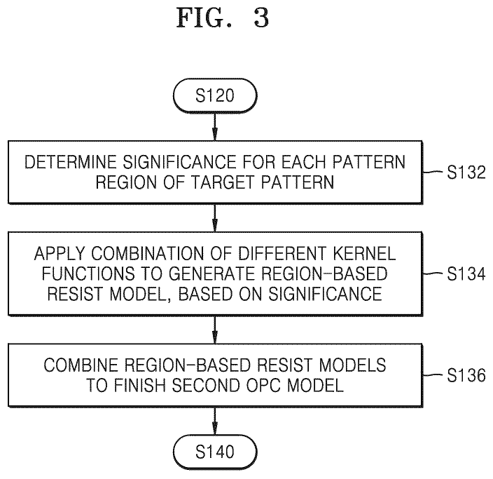

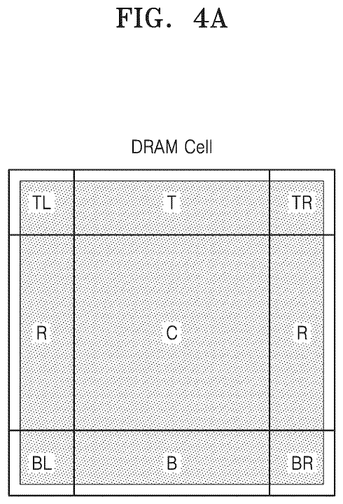

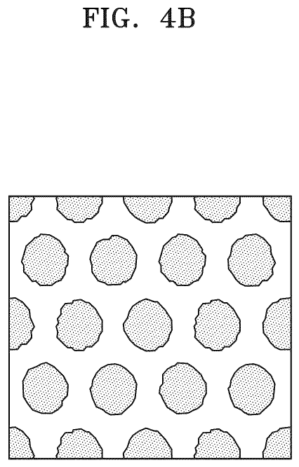

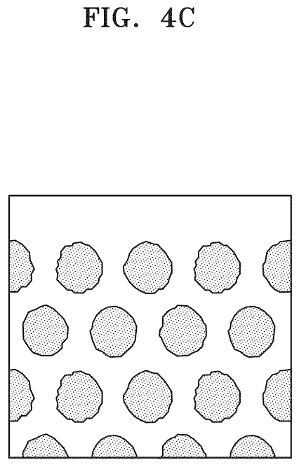

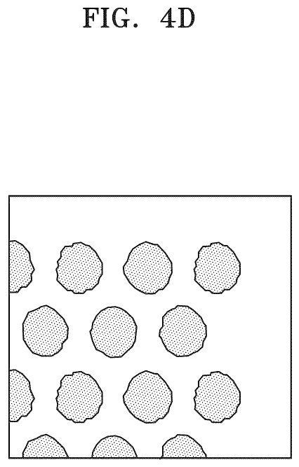

An operation of generating the second OPC model may include an operation of optimizing or improving a threshold value of a PR. Here, the threshold value of the PR may denote or correspond to a threshold value where a chemical change occurs in the exposure process, and for example, the threshold value may be assigned as or be based on an intensity of exposure light. In some example embodiments, the operation of generating the second OPC model may include an operation of selecting and combining appropriate kernel functions from among various resist kernel functions. Here, the kernel function may be or may correspond to a basis function which is used in nonparametric estimation technology and may be used for replicating a characteristic of a resist image in the OPC model. The OPC method according to some example embodiments may apply a combination of different kernel functions for each region in a target pattern and/or in a design layout corresponding thereto, in a process of generating the second OPC model. A combination of different kernel functions for each region is described in more detail with reference to FIGS. 3 to 4D.

Generally, an OPC model may be a generic name for an optical OPC model and an OPC model for PR. Therefore, an operation of generating the OPC model (e.g., an OPC modeling operation) may be a generic name for an operation of generating the optical OPC model and an operation of generating the OPC model for PR. Hereinafter, a generic name for the optical OPC model and the first OPC model may be a first OPC model, and a generic name for the OPC model for PR and the second OPC model may be a second OPC model.

After or at least partly after the second OPC model is generated, an OPC-performed design layout may be obtained by performing a simulation using the OPC model in operation S140. Because the OPC model includes the first OPC model and the second OPC model, a simulation using the OPC model may include a simulation using the first OPC model and a simulation using the second OPC model. An optical image (or an aerial image) generated through a simulation based on the first OPC model is illustrated in the left region of FIG. 2B. Also, PR characteristics and an optical image of the first OPC model may be input to the second OPC model, and a resist image generated through a simulation based on the second OPC model is illustrated in the right region of FIG. 2B. Here, the PR characteristics may include a component of a PR, a developer, and a characteristic such as one or more of the shape, slope, and thickness of the PR.

FIG. 2B is not a simulation image based on an OPC model for the design layout of FIG. 2A. FIG. 2B rather shows a simulation image of each of circular patterns arranged as a two-dimensional (2D) array, for describing a simulation concept based on the first OPC model and the second OPC model. FIG. 2C shows a simulation image based on an OPC model for the design layout of FIG. 2A. In detail, a simulation image of FIG. 2C may be obtained through a simulation based on the first OPC model and the second OPC model for the design layout of FIG. 2A.

For reference, the simulation image of FIG. 2C may be or may correspond to an image corresponding to a target pattern which is an OPC resultant material, and a contour may be extracted therefrom. When the contour is greatly or maximally similar to the target pattern, a design layout corresponding thereto may be obtained as an OPC-performed design layout. As a result, the OPC method may correspond to an operation of sufficiently or maximally making the contour, extracted through the simulation based on the OPC model, similar to the shape of the target pattern. Also, a simulation operation based on the OPC model and a comparison operation may not end at a time and may be repeated, e.g., may be repeated tens to hundreds of times.

To provide a more detailed description, when a design layout is first input to the OPC model, the design layout may be divided into a plurality of segments and may be input to the OPC model. For reference, a segment may be referred to as a fragment and may denote a straight line corresponding to an edge of the design layout or data of the straight line. Subsequently, a simulation image may be generated through a simulation using the OPC model, and a contour corresponding to a target pattern may be extracted from the simulation images. Subsequently, an edge placement error (EPE) may be calculated by comparing the target pattern with the contour. Here, the EPE may denote the difference between an edge of the target pattern and a simulation contour, and moreover, the EPE may be calculated from each of evaluation points which are normally set. Subsequently, positions of the segments may be changed, a contour may be extracted through the simulation using the OPC model again, and the EPE may be calculated. Such a process may be repeated so that the EPE is within a range such as a predetermined range, and/or the number of repetitions reaches a number such as predetermined number of times. After repetition ends, the final design layout may correspond to an OPC-performed design layout.

The OPC method according to various example embodiments may apply a combination of different kernel functions for each pattern region, when generating an OPC model (particularly, a second OPC model which is an OPC model for a PR pattern) and may thus considerably enhance OPC modeling performance. Accordingly, the OPC method according to some example embodiments may obtain an improved or optimal OPC-performed design layout approximate to the target pattern, based on a performance-improved OPC model, and moreover, a good mask for enabling the target pattern to be accurately formed on a wafer may be manufactured based on the optimal OPC-performed design layout.

For reference, recently, the OPC model (particularly, the second OPC model) may be generated based on a certain resist and/or a dry development process to be applied. However, as various variables based on a reduction in pattern size, at least one of a certain resist, dry development, and a temperature change of a post exposure bake (PEB) are added, and a level of difficulty of OPC modeling may increase. Therefore, in an OPC model where a single resist model is applied to an entire region, it may be difficult to enhance consistency. Particularly, in a pattern of a cell region of dynamic random access memory (DRAM), an OPC model, which mainly uses a center portion, may be used, but a problem may occur where the consistency of the OPC model is reduced in an edge portion or a corner portion of the pattern.

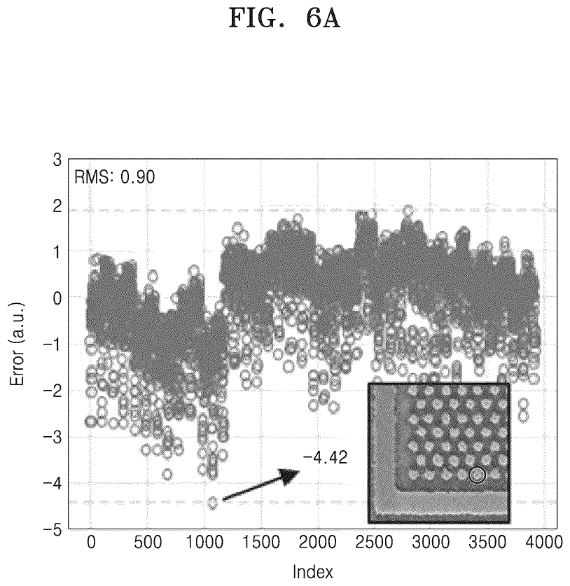

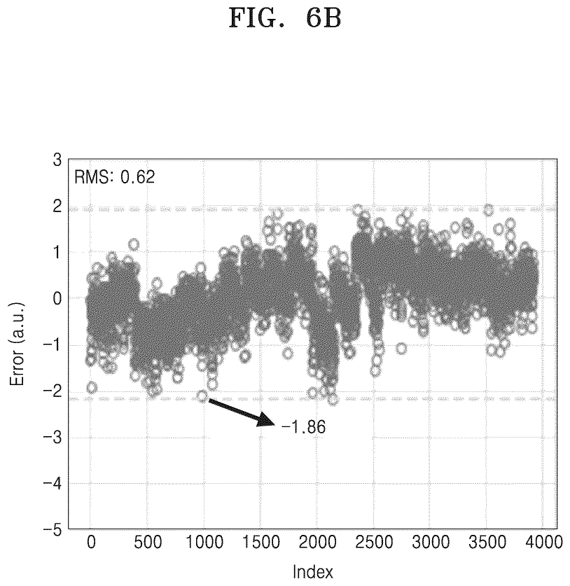

However, the OPC method according to various example embodiments may differently generate and apply a resist model for each region of a pattern and may thus improve the performance of an OPC model to considerably enhance a consistency of the OPC model. In detail, the OPC method according to some example embodiments may differently apply a combination of resist kernel functions for each region of a pattern so as to generate the second OPC model. Furthermore, a difference between a real result pattern of a wafer and an estimation contour of a simulation image of an OPC model may be calculated, for example based on root mean square (RMS), and may compared. An operation of comparing the performance of an OPC model of an OPC method of a comparative example with the performance of an OPC model of an OPC method according to some example embodiments by using RMS is described in more detail with reference to FIGS. 6A and 6B.

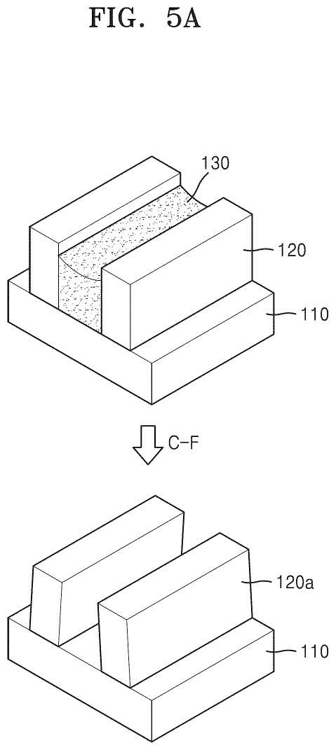

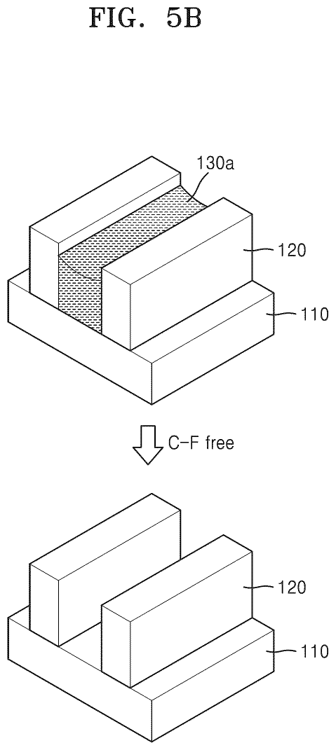

The OPC method according to some example embodiments may be applied to patterns of all layers. In some example embodiments, the OPC method may be usefully applied to a pattern of a cell layer where there are a number of repetition patterns. Moreover, the OPC method according to some example embodiments may be more effectively applied in replicating a patterning process (for example, a patterning process including a dry development process, which has been increasing in significance recently) which may be difficult to replicate through a conventional modeling method. A patterning process including a dry development process is described in more detail with reference to FIGS. 5A and 5B.

FIG. 3 is a flowchart illustrating in more detail an operation of generating a second OPC model in the OPC method of FIG. 1, and FIGS. 4A to 4D are concept diagrams respectively illustrating operations of generating the second OPC model of FIG. 3. FIGS. 4B, 4C, and 4D illustrate an enlarged center portion, an enlarged edge portion, and an enlarged corner portion of FIG. 4A, respectively.

Referring to FIGS. 3 to 4D, in the OPC method according to various example embodiments, operation S130 of generating a second OPC model may first determine the significance of each pattern region of a target pattern or a design layout corresponding thereto in operation S132. The significance of each pattern region may be determined based various criterions. For example, the criterions may include at least one of the number of repetitions of a pattern, the number of same patterns, and a weak point, e.g., a weak point in various patterns.

To describe criterions in more detail, when a criterion is or is based on the number of repetitions of a pattern, the significance of each pattern region may be calculated in proportion to the number of repetitions of the pattern. For example, the significance of a region where the number of repetitions of a pattern is the maximum may be highest, and the significance of a region where the number of repetitions of a pattern is the minimum may be lowest.

Alternatively or additionally, when a criterion is or is based on the number of same patterns, the significance of each pattern region may be calculated so that a high significance is allocated to a region where a number of same patterns are extracted. For example, in a target pattern or a design layout corresponding thereto, the same patterns may be extracted for each region by using pattern matching technology for extracting and analyzing the same patterns. Subsequently, a high or the highest significance may be allocated to a region where the same patterns are maximally extracted, and a low or the lowest significance may be allocated to a region where the same patterns are minimally extracted. For reference, the same pattern may not denote completely the same pattern but may denote a pattern within a similarity range which is set based on the pattern matching technology.

Alternatively or additionally when a criterion is a weak point, the significance of each pattern region may be or calculated so that a high significance is allocated to a region which includes a number of weak points. For example, in a target pattern or a design layout corresponding thereto, weak points may be extracted for each region. Subsequently, a high or the highest significance may be allocated to a region where weak points are maximally extracted, and a low or the lowest significance may be allocated to a region where weak points are minimally extracted.

In operation S130 of generating the second OPC model in the OPC method according to some example embodiments, the significance of each pattern region may be calculated in proportion to the number of repetitions of a pattern. To provide a description with reference to a pattern of a cell region of DRAM, as illustrated in FIGS. 4A to 4D, the cell region of the DRAM may be divided into a center portion (center: C), an edge portion (top: T, right: R, left: L, and bottom: B), and a corner portion (top-left: TL, top-right: TR, bottom-left: BL, and bottom-right: BR). Also, the number of repetitions of a pattern may be largest in the center portion (C), the number of repetitions of a pattern may be second large in the edge portion (T, R, L, and B), and the number of repetitions of a pattern may be smallest in the corner portion (TL, TR, BL, and BR). For reference, the number of repetitions may be calculated as the number of patterns which are provided per unit area, and the edge portion (T, R, L, and B) and the corner portion (TL, TR, BL, and BR) may be less in number or repetitions than the center portion C because there is an empty space where a pattern is not provided in an outer portion. Therefore, the significance of the center portion (C) may be highest, the significance of the edge portion (T, R, L, and B) may be second highest, and the significance of the corner portion (TL, TR, BL, and BR) may be lowest.

After or as the significance of each pattern region is determined, a region-based resist model may be generated by applying a combination of different kernel functions in operation S134. Also, an operation of generating the region-based resist model may be performed in the order from a region having high significance to a region having low significance. Also, the operation of generating the region-based resist model may include an operation of improving or optimizing a kernel parameter. To provide a detailed description with reference to a cell region of DRAM, in operation S134 of generating the region-based resist model, resist models may be generated in descending power of significance and in the order of the center portion (C), the edge portion (T, R, L, and B), and the corner portion (TL, TR, BL, and BR). Also, resist models of the center portion (C), the edge portion (T, R, L, and B), and the corner portion (TL, TR, BL, and BR) may be generated by applying a combination of different kernel functions. For example, a resist model (RIcenter) of a center portion, a resist model (RIedge) of an edge portion, and a resist model (RIcorner) of a corner portion may be expressed as a combination of kernel functions as in the following Equations 1, 2, and 3.

RIcenter=a₀*(AI)+a_{1*}G(AI)+ ⋅ ⋅ ⋅ Equation (1)

RIedge=b₀*(AI)+b₁*G(AI)+b₂*V(AI)+ ⋅ ⋅ ⋅ Equation (2)

RIcorner=c₀*(AI)+c₁*G(AI)+c₂*V(AI)+ ⋅ ⋅ ⋅ Equation (3)

In Equation 1, a₀ and a₁ may denote model parameters of the resist model (RIcenter) of the center portion, and G may denote a kernel function (for example, a Gaussian kernel function). Also, AI may denote an aerial image of a pattern, and G(AI), as in the expression of f(x), may denote that AI is input as a factor to a kernel function. Also, ‘+ ⋅ ⋅ ⋅’ of the latter portion of Equation 1 may denote that another kernel function other than the Gaussian kernel function is included in the resist model (RIcenter) of the center portion so as to more accurately replicate the shape of a pattern of the center portion. However, in some example embodiments, only the Gaussian kernel function may be used in the resist model (RIcenter) of the center portion.

In Equation 2, b₀, b₁, and b₂ may denote model parameters of the resist model (RIedge) of the edge portion, and G and V may denote kernel functions (for example, G may denote the Gaussian kernel function, and V may denote a vision kernel function). Here, the vision kernel function may be a kernel function which reflects a weight, based on the presence of another pattern (for example, a polygon) on the periphery of a pattern, and may reflect an effect of a peripheral pattern distribution. For reference, in performing the OPC method, the pattern may be changed to a combination shape of right-angled figures (e.g., a polygon shape). Also, ‘+ ⋅ ⋅ ⋅’ of the latter portion of Equation 2 may denote that another kernel function other than the Gaussian kernel function and the vision kernel function is included in the resist model (RIcenter) of the edge portion so as to more accurately replicate the shape of a pattern of the edge portion.

In Equation 3, c₀, c₁, and c₂ may denote model parameters of the resist model (RIcorner) of the corner portion, and G and V may denote kernel functions (for example, G may denote the Gaussian kernel function and V may denote the vision kernel function). Also, ‘+ ⋅ ⋅ ⋅’ of the latter portion of Equation 3 may denote that another kernel function other than the Gaussian kernel function and the vision kernel function is included in the resist model (RIcorner) of the corner portion so as to more accurately replicate the shape of the pattern of the corner portion. In the resist model (RIcorner) of the corner portion, comparing with the resist model (RIcenter) of the edge portion, an additional kernel function may be introduced, or fine tuning may be applied to a model parameter. For example, the resist model (RIcorner) of the corner portion may further include a density kernel function. The density kernel function may be a kernel function which reflects a weight, based on whether a density of a pattern is high or low.

In association with generating of a region-based resist model, an operation of optimizing a kernel parameter may denote an operation of improving or optimizing model parameters. For example, in the resist model (RIcenter) of the center portion, an operation of optimizing a kernel parameter may be an operation of detecting appropriate a₀ and a₁, and in the resist model (RIedge) of the edge portion, an operation of optimizing a kernel parameter may be an operation of detecting appropriate b₀, b₁, and b₂. In the resist model (RIcorner) of the corner portion, an operation of optimizing a kernel parameter may be an operation of detecting appropriate c₀, c₁, and c₂. Furthermore, kernel parameter improvement or optimization may be referred to as a model calibration. The model calibration may be performed through focus/defocus, focus centering, mask defocus, and kernel calibration, when data associated with a resist model is input. The data associated with the resist model may include a graphic format of a design layout such as one or more of a graphic data system (GDS), a gauge, information about a calibration method, and a flare map.

After region-based resist models are generated, the second OPC model may be finished by combining the region-based resist models in operation S136. Because another resist model to which a combination of other kernel functions is applied is generated for each pattern region, discontinuity may occur in a boundary between regions when combining region-based resist models. Therefore, in a process of combining region-based resist models, smoothing (e.g., model smoothing) may be performed so that discontinuity does not occur in a boundary between regions. Various linear and/or nonlinear interpolations may be used in model smoothing. For example, in operation S130 of generating the second OPC model of the OPC method according to some example embodiments, a sigmoid function, which is much used in the nonlinear interpolation, may be used in smoothing; however, example embodiments are not limited thereto.

The OPC method according to some example embodiments may include a multi-step-based modeling method which applies different kernel functions for each region to generate and combine resist models, in OPC modeling (e.g., in generating the second OPC model) where the use of a PR is reflected among elements of an OPC model. For example, in a cell region of DRAM, an operation of applying the multi-step-based modeling method to generate the second OPC model is described below. First, a cell region may be divided into a center portion, an edge portion, and a corner portion. In the center portion, a resist model may be generated by using kernel functions which are substantially the same as a general resist model. In the edge portion, a resist model may be generated by additionally applying kernel functions (for example, the vision kernel function and the density kernel function) which may consider a peripheral pattern distribution, compared to the center portion. Further, in the corner portion, a certain process may be performed similar to the edge portion, but based on a characteristic of the corner portion which is high in level of difficulty of patterning, changing of a combination of kernel functions and/or a correction of a calibration option may be performed for fine tuning of a model parameter. Also, in a process of combining region-based resist models, model smoothing may be performed by using the sigmoid function so that a result of OPC is not differently obtained in a boundary between regions, namely, discontinuity does not occur in the boundary between the regions.

For reference, a consistency of an OPC model may decrease and a level of difficulty of OPC modeling may increase, based on a reduction in pattern size, a certain resist in an exposure process, and the application of a development process. For example, in a pattern of a cell region to which a dry development process is applied, when an OPC model of a single resist model based on a combination of the same kernel functions is applied to an entire cell region, a problem may occur where a consistency of an OPC model is reduced in the edge portion and the corner portion. As a detailed example, in a case where a dry development process and a certain resist corresponding thereto are applied to patterning of a cell region of DRAM, when an OPC method using an OPC model of a single resist model is performed, RMS of about 0.55 may be calculated in the center portion and RMS of about 0.90 may be calculated in the edge portion, causing a large reduction in consistency of an OPC model in the edge portion and the corner portion. However, in the OPC method according to some example embodiments, a cell region may be divided into several regions based on a significance and an OPC model may be generated by generating and combining resist models of a combination of different kernel functions for each region, thereby solving a problem where consistency of an OPC model in the edge portion and the corner portion described above is reduced.

FIGS. 5A and 5B are perspective views for comparing and describing a wet development process of a comparative example and a dry development process associated with an OPC method according to various example embodiments, FIG. 5A is a perspective view of the wet development process of the comparative example, and FIG. 5B is a perspective view of the dry development process associated with the OPC method according to some example embodiments.

Referring to FIGS. 5A and 5B, a liquid solvent 130 may be used in the wet development process of the comparative example of FIG. 5A. Therefore, a PR pattern 120 on a lower layer 110 or a substrate may be inclined by a capillary force C-F based on surface tension of the liquid solvent 130. To solve or improve over a problem where the PR pattern 120 is inclined, when the thickness of a PR is thin, a problem may occur where selectivity is reduced in a post etching process.

On the other hand, a gas 130a such as HBr may be used in the dry development process associated with the OPC method according to various example embodiments as described in FIG. 5B. Therefore, because there is no capillary force based on surface tension C-Ffree, a problem may not occur where the PR pattern 120 on the lower layer 110 or the substrate is inclined. Accordingly, the thickness of a PR may increase thickly, and thus, selectivity may be maintained or may be more likely to be maintained to be high in a post etching process.

On the other hand, as described above, in the dry development process, due to a pattern fining process, an increase in PR thickness, and the use of a resist differing from a wet development process, in a case where the OPC method is performed by applying an OPC model of a single resist model to an entire cell region, there may be a problem where consistency of the OPC model is reduced in the edge portion and/or the corner portion. However, in the OPC method according to some example embodiments, the OPC method may be performed by applying an OPC model of a different resist model for each region and may thus solve or improve upon a problem where consistency of the OPC model is reduced in the edge portion and/or the corner portion.

FIGS. 6A and 6B are graphs showing a comparison result of performance of an OPC model of an OPC method of a comparative example and performance of an OPC model of an OPC method according to some example embodiments, FIG. 6A shows errors with respect to positions in the OPC method of the comparative example, and FIG. 6B shows errors with respect to positions in the OPC method according to some example embodiments. In each of the graphs of FIGS. 6A and 6B, the x axis represents a position index, the y axis represents an error and/or a difference or scaled difference between a critical dimension (CD) of a real pattern and a CD of a simulation image of the OPC method, and a unit may be an arbitrary unit.

Referring to FIGS. 6A and 6B, the OPC method of the comparative example of FIG. 6A may be or correspond to an OPC model of a single resist model. As seen in FIG. 6A, the maximum error may be represented by −4.42, and RMS may be calculated to be about 0.90. For reference, a region where RMS is calculated may be a corner portion and/or an edge portion of a cell region corresponding to a scanning electron microscope (SEM) photograph such as a CD-SEM photograph, and a pattern where the maximum error occurs may correspond to a fifth pattern of the lowermost line in the SEM photograph.

The OPC method of FIG. 6B according to some example embodiments may be based on an OPC model where multi resist models for each region are combined. As seen in FIG. 6B, the maximum error may be represented by −1.86, and RMS may be calculated to be about 0.62. For reference, a region where RMS is calculated may be a corner portion and/or an edge portion of a cell region corresponding to an SEM photograph of FIG. 6A, and a pattern where the maximum error occurs may correspond to a fifth pattern of the lowermost line in the SEM photograph. In the OPC method according to some example embodiments, it may be seen that RMS largely decreases by 0.62 compared to the OPC method of the comparative example, and the maximum error decreases by ½ or less compared to the OPC method of the comparative example. Accordingly, it may be seen that consistency of the OPC model of the OPC method according to some example embodiments is largely enhanced in a corner portion and/or an edge portion.

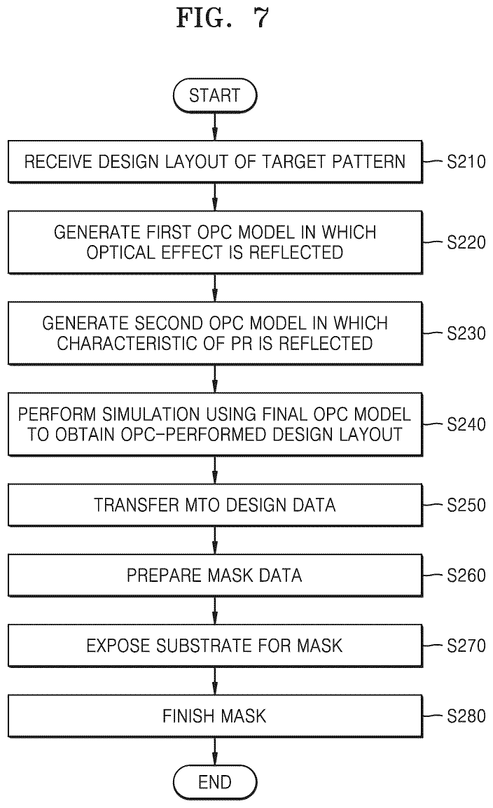

FIG. 7 is a flowchart schematically illustrating a process of a method of manufacturing a mask by using an OPC method, according to some example embodiments. FIG. 7 is described with reference to FIGS. 1 to 4, and descriptions which are the same as or similar to the descriptions of FIGS. 1 to 6B are briefly given or are omitted.

In a method of manufacturing a mask (hereinafter, simply referred to as a mask manufacturing method) by using the OPC method according to some example embodiments, operation S210 of receiving a design layout of a target pattern, operation S220, operation S230, and operation S240 of obtaining an OPC-performed design layout may be sequentially performed. Operation S210 of receiving the design layout of the target pattern, operation S220, operation S230, and operation S240 of obtaining the OPC-performed design layout may be the same as the descriptions of operation S110 of receiving the design layout of the target pattern, operation S120, operation S130, and operation S140 of obtaining the OPC-performed design layout in the OPC method of FIG. 1.

Subsequently, mask tape-out (MTO) design data may be transferred to a mask manufacturing team in operation S250. Generally, MTO may denote that data of the final design layout obtained through the OPC method is transferred to the mask manufacturing team, and a request to manufacture a mask is transferred to the mask manufacturing team. Accordingly, in the mask manufacturing method according to some example embodiments, MTO design data may denote an OPC-performed design layout obtained through the OPC method or data thereof. The MTO design data may have a graphic data format which is used in electronic design automation (EDA) software. For example, the MTO design data may have a data format such as graphic data system II (GDS2) and/or of open artwork system interchange standard (OASIS).

Subsequently, mask data preparation (MDP) may be performed in operation S260. The MDP may include, for example, i) format conversion called fracturing, ii) augmentation of a bar code for mechanical readout, a standard mask pattern for inspection, and a job deck, and iii) verification based on an automatic scheme and a manual scheme. Here, the job deck may denote an operation of generating a text file corresponding to a series of instructions such as arrangement information about multi mask files, a reference dose, and an exposure speed or process.

The format conversion (e.g., fracturing) may denote an operation of segmenting the MTO design data by region units to convert the MTO design data into a format for an electron beam writer. The fracturing may include, for example, data manipulation such as size scaling, sizing of data, rotation of data, pattern reflection, and color conversion. In a conversion process based on fracturing, data of many systematic errors occurring in a certain portion of a transfer process of an image on a wafer from design data may be corrected.

A data correction process on the systematic errors may be referred to as mask process correction (MPC) and, for example, may include line width adjustment called CD adjustment and an operation of increasing a precision of pattern arrangement. Accordingly, the fracturing may contribute to enhancing the quality of the final mask and moreover, may be a process which is preferentially performed for MPC. Here, the systematic errors may be caused by distortion occurring in an exposure process, a mask development and etching process, and a wafer imaging process.

Also, the MDP may include MPC. The MPC, as described above, may denote a process of correcting an error (e.g., a systematic error) occurring in an exposure process. Here, the exposure process may be a concept which overall includes electron beam writing, development, etching, and baking. Furthermore, data processing may be performed before the exposure process. The data processing may be a preprocessing process on a kind of mask data and may include exposure time prediction and grammar check on the mask data.

After the MDP is performed, a substrate for mask may be exposed based on the mask data in operation S270. Here, exposure may denote, for example, electron beam writing. Here, the electron beam writing may be performed by, for example, a gray writing process using a multi-beam mask writer (MBMW). Moreover, the electron beam writing may be performed by using a variable shape beam (VSB) writer. However, example embodiments are not limited thereto.

After the MDP is performed, a process of converting mask data into pixel data may be performed before the exposure process. The pixel data may be data which is directly used in actual exposure and may include data of a shape which is to be exposed and data of a dose allocated to each of the pieces of data. Here, data of a shape may be bit-map data which is obtained through conversion based on rasterization of shape data which is vector data.

After the exposure process is performed, a mask may be finished by performing a series of processes in operation S280. The series of processes may include, for example, a process such as development, etching, and cleaning. Also, a series of process for mask manufacturing may include a measurement process or a defect test or defect repair process. Furthermore, the series of process for mask manufacturing may include a pellicle coating or attachment process. Here, the pellicle coating process may denote a process which attaches a pellicle for protecting a surface of a mask from subsequent pollution during a delivery period of the mask and an available lifetime period of the mask, when it is checked through final cleaning and test that there are no or reduced pollutants and/or chemical smears.

Subsequently, after finishing the mask in operation S280, a semiconductor device may be fabricated based on the finished mask. For example, the semiconductor device may be or may include a DRAM device; example embodiments are not limited thereto.

Herein above, various example embodiments have been described in the drawings and the specification. Embodiments have been described by using the terms described herein, but this has been merely used for describing the inventive concept and has not been used for limiting a meaning or limiting the scope of the inventive concept defined in the following claims. Therefore, it may be understood by those of ordinary skill in the art that various modifications and other equivalent embodiments may be implemented from the inventive concept. Accordingly, the spirit and scope of the inventive concept may be defined based on the spirit and scope of the following claims.

While inventive concepts have been particularly shown and described with reference to embodiments thereof, it will be understood that various changes in form and details may be made therein without departing from the spirit and scope of the following claims. Additionally, example embodiments are not necessarily mutually exclusive with one another. For example, some example embodiments may include one or more features described with reference to one or more figures and may also include one or more other features described with reference to one or more other figures.

What is claimed is:

1. An optical proximity correction (OPC) method comprising:
receiving a design layout of a target pattern;
generating a first OPC model of an OPC model on the design layout, in which an optical effect of an exposure process is reflected;
generating a second OPC model in which a characteristic of a photoresist in the exposure process is reflected; and
performing a simulation using the first and second OPC models to obtain an OPC-performed design layout,
wherein the generating the second OPC model comprises,
differently applying a combination of kernel functions, used in the second OPC model, to each pattern region.

2. The OPC method of claim 1, wherein the generating the second OPC model comprises calculating a significance for each pattern region to perform kernel parameter improvement in descending power of significance.

3. The OPC method of claim 2, wherein the calculating the significance includes calculating in proportion to a number of repetitions of a pattern.

4. The OPC method of claim 2, wherein
the target pattern includes a pattern of a cell region of dynamic random access memory (DRAM), and
the calculating the significance includes calculating, in the cell region, in order of a center portion with a first number of repetitions of a pattern, an edge portion with a second number of repetitions of the pattern less than the first number, and a corner portion with a third number of repetitions of the pattern less than the second number.

5. The OPC method of claim 4, wherein,
in the edge portion and the corner portion, the method includes adding a kernel function in which changes in distribution and density of a peripheral pattern are reflected to the combination of kernel functions.

6. The OPC method of claim 2, wherein the calculation includes calculating a high significance in a region where a number of same patterns are extracted, based on pattern matching technology for extracting and analyzing the same patterns.

7. The OPC method of claim 2, wherein the calculating includes calculating a high significance in a region where a number of weak points are provided.

8. The OPC method of claim 1, wherein,
in the generating the second OPC model,
correction based on the second OPC model comprises smoothing so that discontinuity does not occur in a boundary portion for each pattern region.

9. The OPC method of claim 8, wherein the smoothing includes using a sigmoid function.

10. The OPC method of claim 2, wherein,
in the kernel parameter improvement,
the method includes calculating a difference between a real result pattern and a contour obtained by the simulation based on root mean square (RMS), and
detecting a kernel parameter for reducing the RMS.

11. An optical proximity correction (OPC) method comprising:
receiving a design layout of a target pattern;
generating a first OPC model of an OPC model on the design layout, in which an optical effect of an exposure process is reflected;
generating a second OPC model in which a characteristic of a photoresist in the exposure process is reflected; and
performing a simulation using the first and second OPC models to obtain an OPC-performed design layout,
wherein the generating the second OPC model comprises,
determining a significance for each pattern region of the target pattern,
applying a combination of different kernel functions to generate region-based resist models, based on the significance, and
combining the region-based resist models to provide the second OPC model.

12. The OPC method of claim 11, wherein the generating the region-based resist models comprises performing kernel parameter improvement for each region where the significance is high.

13. The OPC method of claim 11, wherein
the determining the significance includes calculating based on at least one of a number of repetitions of a pattern, a number of extracted same patterns, and a number of weak points.

14. The OPC method of claim 11, wherein
the target pattern includes a pattern of a cell region of dynamic random access memory (DRAM),
the determining the significance includes calculating in an order of a center portion, an edge portion, and a corner portion in the cell region, and
in the edge portion and the corner portion, the method includes adding a kernel function in which changes in distribution and density of a peripheral pattern are reflected to the combination of kernel functions.

15. The OPC method of claim 11, wherein,
in the generating the second OPC model,
correction based on the second OPC model comprises smoothing so that discontinuity does not occur in a boundary portion for each pattern region.

16. A method of manufacturing a mask, the method comprising:
receiving a design layout of a target pattern;
generating a first optical proximity correction (OPC) model of an OPC model on the design layout, in which an optical effect of an exposure process is reflected;
generating a second OPC model in which a characteristic of a photoresist in the exposure process is reflected;
performing a simulation using the first and second OPC models to obtain an OPC-performed design layout;
transferring data of an OPC-performed design layout as mask tape-out (MTO) design data;
preparing mask data based on the MTO design data; and
performing exposure on a substrate for mask, based on the mask data,
wherein the generating the second OPC model comprises
differently applying a combination of kernel functions, used in the second OPC model, to each pattern region.

17. The method of claim 16, wherein the generating the second OPC model comprises calculating a significance for each pattern region to perform kernel parameter optimization in descending power of significance.

18. The method of claim 17, wherein the calculating the significance includes calculating based on at least one of a number of repetitions of a pattern, a number of extracted same patterns, and a number of weak points.

19. The method of claim 17, wherein
the target pattern includes a pattern of a cell region of dynamic random access memory (DRAM),
the calculating the significance includes calculating in an order of a center portion, an edge portion, and a corner portion in the cell region, and
in the edge portion and the corner portion, the method includes adding a kernel function in which changes in distribution and density of a peripheral pattern are reflected to the combination of kernel functions.

20. The method of claim 16, wherein,
in the generating the second OPC model,
correction based on the second OPC model comprises smoothing so that discontinuity does not occur in a boundary portion for each pattern region.
